(19) United States
(12) Patent Application Publication
(10) Pub. No.: US 2009/0035907 A1
(43) Pub. Date: Feb. 5, 2009

(54) METHOD OF FORMING STACKED GATE STRUCTURE FOR SEMICONDUCTOR MEMORY

(75) Inventor: Takafumi IKEDA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/035,829

(22) Filed: Feb. 22, 2008

(30) Foreign Application Priority Data
Feb. 22, 2007 (JP) 2007-042408

(51) Int. Cl. H01L 21/336

(52) U.S. Cl. 438/266; 257/E21.422

(57) ABSTRACT

A method of manufacturing a nonvolatile semiconductor memory comprising: forming a gate insulating film formed on a surface of a semiconductor substrate; forming a source region and a drain region in the semiconductor substrate; forming a floating gate electrode on the gate insulating film; forming a inter-gate insulating film on the floating gate electrode; forming a control gate electrode on the inter-gate insulating film; forming a source contact region wherein the source contact region is electrically contact to said source region, and top part of said source contact region is lower than bottom part of said control gate electrode.

### CROSS-REFERENCE TO RELATED APPLICATIONS

This application is based upon and claims the benefit of priority from the prior-Japanese Patent Application No. 2007-42408, filed Feb. 22, 2007, the entire contents of which are incorporated herein by reference.

### BACKGROUND OF THE INVENTION

1. Field of the Invention

The present invention relates to a non-volatile semiconductor memory, and particularly to a memory cell transistor having a stacked gate structure.

2. Description of the Related Art

For example, NAND or NOR type flash memories are used as non-volatile semiconductor memories in electronic equipment. In the NOR type flash memory, a memory cell transistor is a MOS (Metal Oxide Semiconductor) transistor having a stacked gate structure comprising a control gate electrode and a floating gate electrode, for example. The stacked gate structure is formed in the line & space style in the memory cell array portion, and thus the channel region and the source/drain diffusion layer of the memory cell transistor can be easily scaled down (miniaturized).

On the other hand, the miniaturization of a contact portion provided to connect bit lines and source lines to the source and drain diffusion layer is not easy. The contact portion is formed after the stacked gate electrode and the source/drain diffusion layer are formed. Therefore, a contact hole in which the contact portion is embedded is formed in an aspect ratio based on the height of the stacked gate electrode. Accordingly, the source/drain diffusion layer is increased in size because of the embedding property of a contact member into the contact hole, securement of short margin between the contact portion and the gate electrode, etc.

This problem is particularly severe in the memory cell transistor having the stacked gate structure, and the miniaturization of the contact portion has not yet followed the miniaturization of the whole of the memory cell array portion. Therefore, the fraction of the total memory cell array area occupied by contacts tends to increase as the device density increases.

Furthermore, in order to solve the above problem a method known as SAS (Self-Aligned Source) has been frequently used for providing no source-line contact portion, but forming a source diffusion layer so as to be common in the extending direction of the word line and substituting the diffusion layer concerned for the contact portion. However, SAS has a larger resistance than a contact plug made of tungsten (W) or a similar material. Therefore, shunt areas are provided at fixed intervals in the memory cell array portion. A source line having lower electrical resistivity than SAS is formed on the upper portion of SAS within the shunt area, and both are connected to each other through the contact portion.

### BRIEF SUMMARY OF THE INVENTION

A method of manufacturing a nonvolatile semiconductor memory comprising: forming a gate insulating film formed on a surface of a semiconductor substrate; forming a source region and a drain region in the semiconductor substrate; forming a floating gate electrode on the gate insulating film; forming a inter-gate insulating film on the floating gate electrode; forming a control gate electrode on the inter-gate insulating film; forming a source contact region wherein the source contact region is electrically contact to said source region, and top part of said source contact region is lower than bottom part of said control gate electrode.

### BRIEF DESCRIPTION OF THE SEVERAL VIEWS OF THE DRAWINGS

FIG. 1 is a plan view showing a memory cell array portion according to a first embodiment;

FIG. 2 is a cross-sectional view taken along the II-II line of FIG. 1;

FIG. 3 is a cross-sectional view taken along the III-III line of FIG. 1;

FIG. 4 is a cross-sectional view taken along the IV-IV line of FIG. 1;

FIG. 5 is a cross-sectional view showing a manufacturing process of the embodiment;

FIG. 6 is a cross-sectional view showing a manufacturing process of the embodiment;

FIG. 7 is a cross-sectional view showing a manufacturing process of the embodiment;

FIG. 8 is a cross-sectional view showing a manufacturing process of the embodiment;

FIG. 8A is a plan view showing a manufacturing process of the embodiment;

FIG. 8B is a cross-sectional view taken along the VIIIB-VIIIB line of FIG. 8A;

FIG. 9 is a cross-sectional view showing a manufacturing process of the embodiment;

FIG. 10 is a cross-sectional view showing a manufacturing process of the embodiment;

FIG. 11A is a cross-sectional view showing a manufacturing process of the embodiment;

FIG. 11B is a cross-sectional view showing a manufacturing process of the embodiment;

FIG. 12 is a plan view showing the structure of an application example;

FIG. 13 is a cross-sectional view taken along the XIII-XIII line of FIG. 12;

FIG. 14 is a cross-sectional view showing a step of the manufacturing process of the application example;

FIG. 15 is a cross-sectional view showing a modification;

FIG. 16 is a cross-sectional view showing the structure of a second embodiment;

FIG. 17 is a cross-sectional view showing a step of the manufacturing process of the second embodiment;

FIG. 18 is a cross-sectional view showing the structure of a third embodiment;

FIG. 19 is a cross-sectional view showing a step of the manufacturing process of the third embodiment; and

FIG. 20 is a cross-sectional view showing a step of the manufacturing process of the third embodiment.

### DETAILED DESCRIPTION OF THE INVENTION

### 1. Summary

A non-volatile semiconductor memory according to an embodiment of the present invention relates to a memory cell transistor having a stacked gate structure.

For example, in the NOR type flash memory, a contact portion is provided to connect a diffusion layer of the memory cell transistor to a source line or a bit line. The contact portion comprises one or two or more contact layers.

The embodiment of this invention has a feature that the upper end of a source-line contact portion in contact with a source diffusion layer is located at a lower position than the lower end of a control gate electrode when the contact portion is constructed by two or more contact layers. Here, a lower end direction is defined as a substrate direction, and an upper end direction is defined as the opposite direction to the substrate direction. Here, “located at a lower position” is defined as “located at a position in the substrate direction (at the substrate side) as compared with a comparison target member/site”.

A contact hole in which the contact portion in contact with the source diffusion layer is embedded is formed in an aspect ratio based on the height of a floating gate electrode. Therefore, as compared with the aspect ratio when the contact hole is formed in the height of the stacked gate electrode, the aspect ratio can be reduced, and the size of the diffusion layer can be reduced. Thus, according to the embodiment of the present invention, the memory cell transistor can be scaled down further, and the size of the memory cell array portion can be reduced.

Furthermore, in the structure of the embodiment of the present invention, the contact portion which comes into contact with the source diffusion layer is formed at a step previous to a step of forming a control gate electrode. That is, the embodiment of the present invention adopts a manufacturing method of forming two gate electrodes to be stacked in different steps. Therefore, in the embodiment of this invention, a method of manufacturing the above structure will be described. The source-line and bit-line contact portions described with reference to this embodiment are defined as contact portions located below the source line and the bit line.

### 2. Embodiments

Next, some possible embodiments will be described.

The embodiments of the present invention will be described in detail by using a NOR type flash memory as an example.

The definition of the contact portion is as described in summary.

### (1) First Embodiment

### (a) Example

### (i) Structure

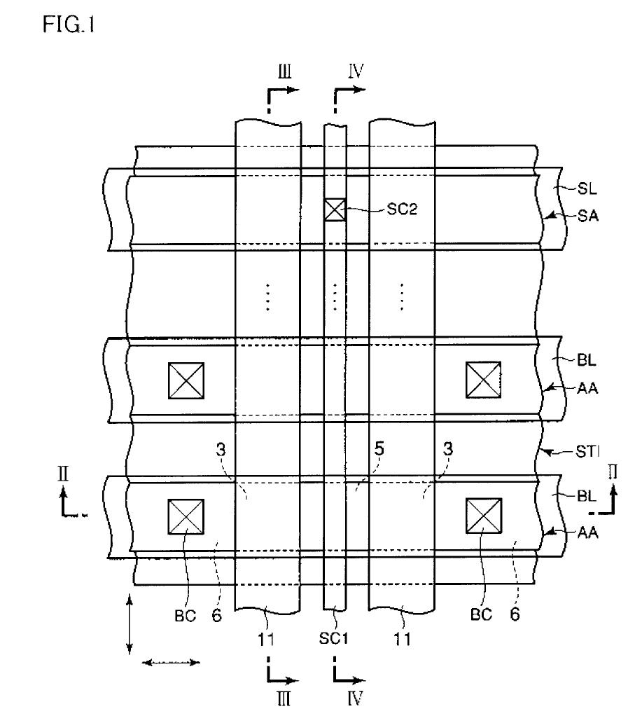

The structure of this embodiment will be described with reference to FIGS. 1 to 4.

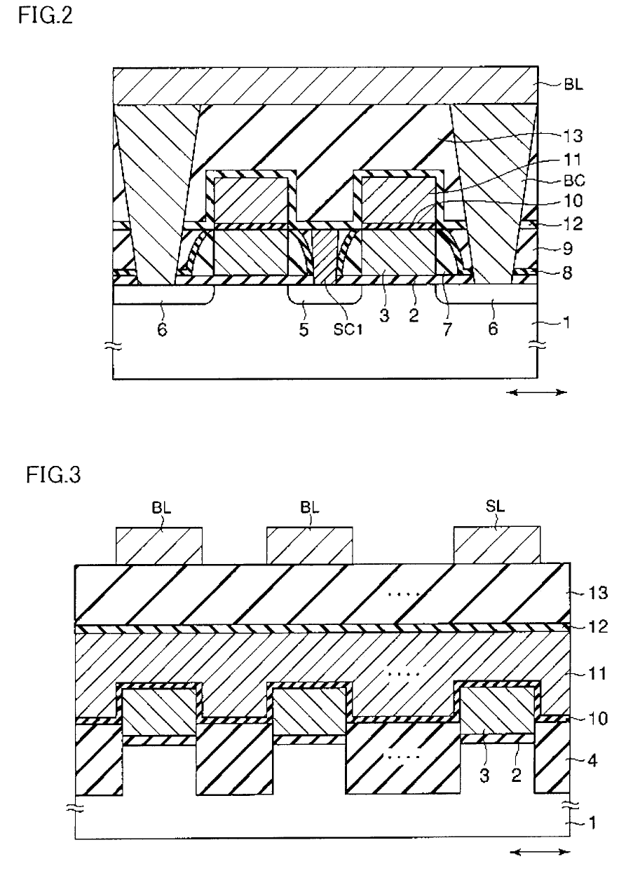

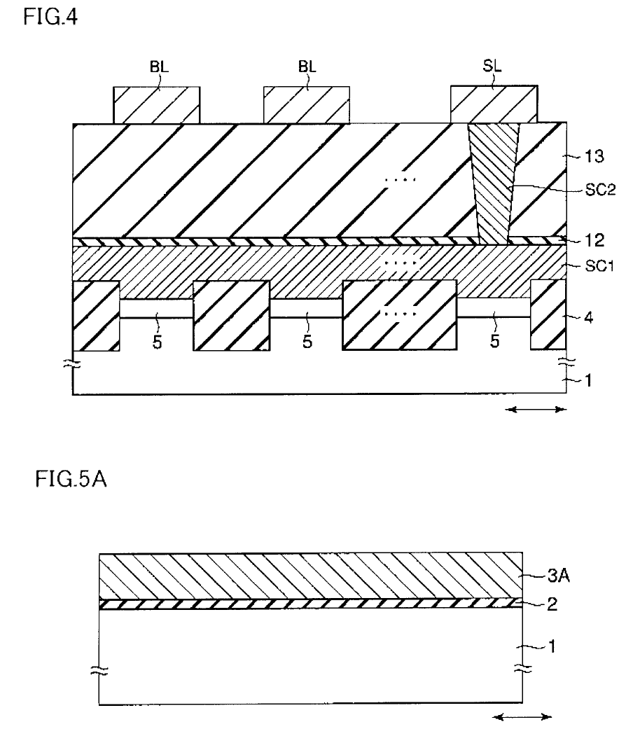

FIG. 1 is a plan view showing a memory cell array portion of an NOR type flash memory, FIG. 2 is a cross-sectional view taken along line II-II of FIG. 1, FIG. 3 is a cross-sectional view taken along line III-III of FIG. 1, and FIG. 4 is a cross-sectional view taken along line IV-IV of FIG. 1.

As shown in FIG. 1, the memory cell array portion has active areas AA and element separating areas STI for electrically separating the active areas AA from one another. Memory cell transistors are arranged in a matrix form on the active areas AA surrounded by the element separating areas STI.

In the NOR type flash memory, a bit-line contact portion BC is connected to the drain diffusion layer 6 of one memory cell transistor, and a first source-line contact portion SC1 is connected to the source diffusion layer 5 of the memory cell transistor. The source-line contact portion SC1 extends in a direction traversing the active area AA (channel width direction).

The bit line BL extends in the channel length direction in the upper layer of the active area AA. The source line SL is provided to the upper layer of the shunt area SA which is provided in the memory cell array portion, and extends in the channel length direction as in the case of the bit line BL. The source line SL is connected to the first source-line contact portion SC1 through a second source-line contact portion SC2 which is provided in the shunt area SA. The shunt area SA is provided every 64 active areas AA, for example. Furthermore, a control gate electrode 11 which also serves as a word line extends in a direction perpendicular to the extending direction of the bit line BL.

As shown in FIGS. 2 to 4, the memory cell transistor has a stacked gate structure comprising the floating gate electrode 3 and the control gate electrode 11. The height of the stacked gate is set to about 300 nm, for example.

The floating gate electrodes 3 are disposed on gate insulating film 2 formed on the surface of the semiconductor substrate 1. The floating gate electrodes 3 adjacent in the channel width direction are electrically separated from each other by an element separating insulating layer 4 having an STI (Sallow Trench Isolation) structure. The floating gate electrodes 3 are formed of polysilicon, for example.

Furthermore, for example, a spacer insulating layer 7 is formed on the side wall in the channel length direction of the floating gate electrode 3.

The control gate electrode 11 is disposed on the floating gate electrode 3 through inter-electrode insulating film 10. The control gate electrode 11 functions as a word line, and thus it extends in the channel width direction and is jointly owned by the memory cell transistors adjacent in the channel width direction. The control gate electrode 11 is formed of polysilicon, for example. In this embodiment, the control gate electrode has a one-layer structure, however, it may be a control gate electrode having a double-layer structure comprising polysilicon film and silicide film formed on the polysilicon film.

Furthermore, as shown in FIG. 3, the control gate electrode 11 may be formed so as to cover the side portion in the channel width direction of the floating gate electrode 3 through the inter-electrode insulating film 10. The coupling ratio between the floating gate electrode 3 and the control gate electrode 11 can be enhanced by the above structure.

The source diffusion layer 5 and the drain diffusion layer 6 are formed as the source/drain area of the memory cell transistor on the surface of the semiconductor substrate 1. The source and drain diffusion layers 5, 6 are jointly owned by the memory cell transistors adjacent in the channel length direction.

The drain diffusion layer 6 is electrically connected to the bit line BL through the bit-line contact portion BC. The bit-line contact portion is embedded in a tapered contact hole. The bit line BL is jointly owned by the memory cell transistors adjacent in the channel length direction.

The source diffusion layer 5 is electrically connected to the source line SL through the two contact layers of the first and second source-line contact portions SC1, SC2. The source-line contact portions SC1, SC2 are formed of tungsten (W), for example. The source line SL is formed of a metal material having low resistivity such as aluminum (Al), copper (Cu) or the like. Intermediate metal film and a contact portion for connecting the intermediate metal film to the source line SL and the bit line may be provided between the source line SL, the bit line BL and the contact portions BC, SC1, SC2.

The source line and bit line contact portions described in this embodiment are defined as contact portions located at lower layers (substrate direction) than the source line and the bit line.

The first source-line contact portion SC1 is embedded in a slit-shaped contact hole formed in the first insulating layer 9, and comes in contact with the source diffusion layer 5. As shown in FIG. 4, the first source-line contact portion SC1 is commonly connected between the source diffusion layers 5 of the memory cell transistors adjacent in the channel width direction. That is, the first source-line contact portion SC1 extends in the channel width direction on the element separating area STI and on the active area AA.

The second source-line contact portion SC2 is provided in the shunt area SA. The first source-line contact portion SC1 is connected to the source line SL in the shunt area SA by the second source-line contact portion SC2.

As described above, the first source-line contact portion SC1 is jointly owned by the memory cell transistors adjacent in the channel width direction. Therefore, the first source-line contact portion SC1 may be also used as a source line extending in the extension direction of the word line, and a source voltage may be supplied from the source-line contact portion SC1 to the memory cell transistor. In this case, it is unnecessary to provide the source line SL and the second contact portion SC2 as shown in FIGS. 1 to 4.

Furthermore, in this embodiment, the source line SL is provided in the same layer as the bit line BL. However, the bit line BL and the source line SL may be provided in different layers by using intermediate metal film.

In this embodiment, the upper end of the first source-line contact portion SC1 which comes into contact with the source diffusion layer 5 is located at a position lower than the lower end of the control gate electrode 11. Here, the lower end direction is defined as the substrate direction, and the upper end direction is defined as the opposite direction to the substrate. “located at the lower position” is defined as “located in the substrate direction (at the substrate side) as compared with a comparison target member/side)”.

The aspect ratio when the contact hole is formed is determined by the size ratio (D/W) of the depth (height) D to the opening width W.

The aspect ratio of the contact hole in which the first source-line contact portion SC1 is embedded is determined by the film thickness (height) of the floating gate electrode 3 and the size in the channel length direction of the source diffusion layer 5.

Accordingly, the size in the height direction of the contact hole is reduced, and thus the aspect ratio can be reduced. Even when the size in the width direction of the contact hole is reduced, the aspect ratio required to form the contact hole can be maintained.

Therefore, it is unnecessary that the size in the channel length direction of the source diffusion layer 5 is increased to secure the aspect ratio of the contact hole in which the first source-line contact portion SC1 is embedded. Accordingly, the size in the channel length direction of the source diffusion layer 5 can be reduced.

As described above, according to the first embodiment of the present invention, the memory cell transistor can be miniaturized, and the size of the memory cell array portion can be reduced.

A method of manufacturing the above structure will be described hereunder.

### (ii) Manufacturing Method

In order to attain the above structure, the first source-line contact portion SC1 is formed before the control gate electrode 11 is formed.

That is, the structures of the memory cell transistor and the source-line contact portion can be attained by forming the control gate electrode and the floating gate electrode separately from each other without using any self-alignment method of subjecting the control gate electrode and the floating gate electrode to gate processing at the same time.

This manufacturing method will be described hereunder in detail.

The manufacturing method according to the first embodiment will be described with reference to FIGS. 5A to 10.

First, as shown in FIGS. 5A and 5B, gate insulating film 2 formed of silicon oxide film is formed on the surface of the semiconductor substrate 1 by the thermal oxidation method, for example. Subsequently, polysilicon film 3A is deposited on the gate insulating film 2 by the CVD (Chemical Vapor Deposition) method, for example.

Then, the polysilicon film 3A is subjected to patterning of line & space so as to have a desired gate width. Thereafter, the polysilicon film 3A and the semiconductor substrate 1 are successively etched by RIE (Reactive Ion Etching), for example, whereby the polysilicon film 3A having a desired gate width and an element separating groove having STI (Shallow Trench Isolation) structure are formed, for example.

Subsequently, silicon oxide is deposited on the whole surface of the semiconductor substrate 1, for example by the HDP-CVD (High Density Plasma CVD) method, so as to be filled in the element separating groove. Thereafter, silicon oxide is flattened, for example by the CMP (Chemical Mechanical Polishing) method, so as to be coincident with the upper end of the polysilicon film 3A. In this case, the element separating insulating layer 4 having the STI structure is formed in the semiconductor substrate 1.

The polysilicon film 3A is subjected to patterning of line & space so as to have a desired gate length. At this time, the patterning is performed so that the gate interval of an area in which a bit-line contact portion will be formed in a subsequent step is larger than the gate interval of an area in which a source-line contact portion will be formed, for example. Then, the polysilicon film 3A is etched on the basis of the pattern concerned by RIE, for example.

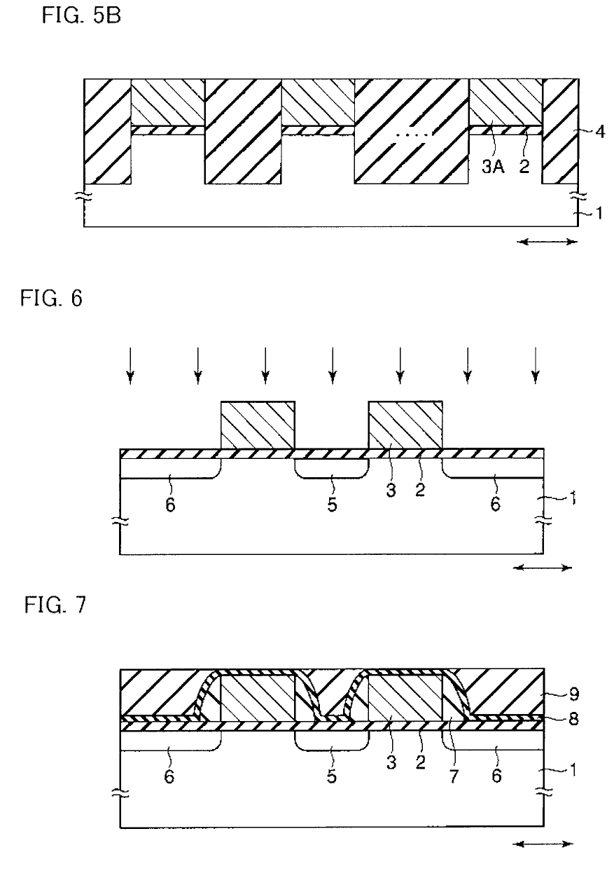

In this case, the floating gate electrode 3 is formed as shown in FIG. 6. The source diffusion layer 5 and the drain diffusion layer 6 are formed in self-alignment on the surface of the semiconductor substrate 1 by using the floating gate electrode 3 as a mask according to the ion implantation method, for example. Thereafter, for example, SiN is deposited so as to cover the whole surface of the semiconductor substrate 1 by the CVD method, for example, and then SiN is etched back.

At this time, as shown in FIG. 7, the spacer insulating layer 7 is formed on the side wall of the floating gate electrode 3. At this time, a recess portion defined by the spacer insulating layer 7 is formed on the source diffusion layer 5. The spacer insulating layer 7 is not necessarily formed when the short margin between the source line contact and the gate electrode which will be afterwards formed is secured.

Thereafter, for example, SiN film 8 which will become stopper film for CMP in a subsequent step is formed so as to cover the whole surface of the semiconductor substrate 1. Furthermore, the first insulation layer 9 formed of BPSG (Boron Phosphorous Silicate Glass), TEOS or the like is formed by using the HDP-CVD method and the surface is planarized by the CMP method so that the upper end thereof is coincident with the upper end of the SIN film 8 as stopper film.

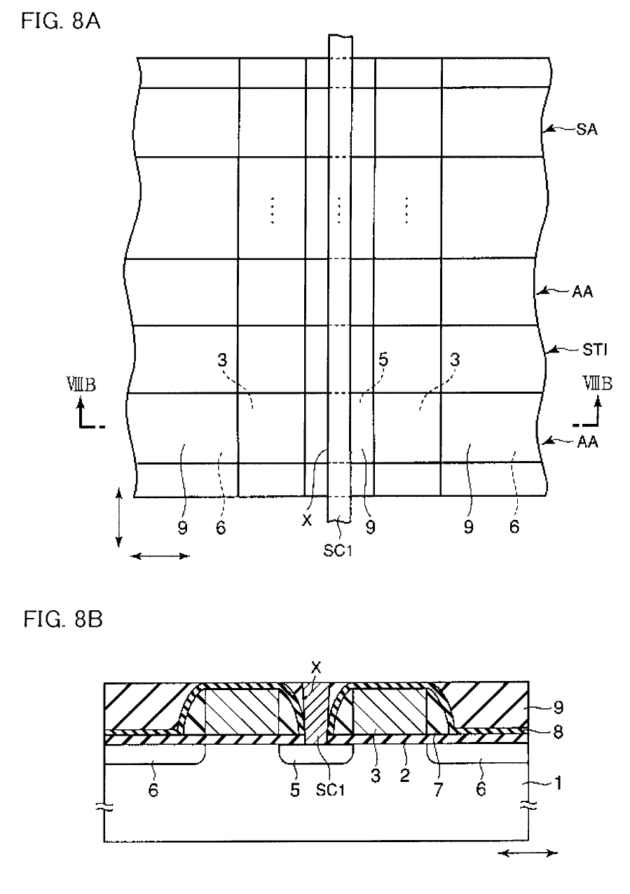

Next, as shown in FIGS. 8A and 8B, a contact hole X is formed in the insulating layer 9 by RIE so that the surface of the source diffusion layer 5 is exposed. An aspect ratio to form the contact hole X is determined in proportion to the film thickness (height) of the floating gate electrode 3. Accordingly, the aspect ratio can be reduced as compared with the case where the aspect ratio is determined on the basis of the height of the stacked gate, and thus the size of the source diffusion layer 5 can be reduced. Furthermore, the contact hole X has a slit structure extending in the channel width direction.

Subsequently, the first source-line contact portion SC1 which is formed, for example, of tungsten (W) is embedded in the contact hole X so as to be coincident with the upper end of the SiN film 8 as the stopper film.

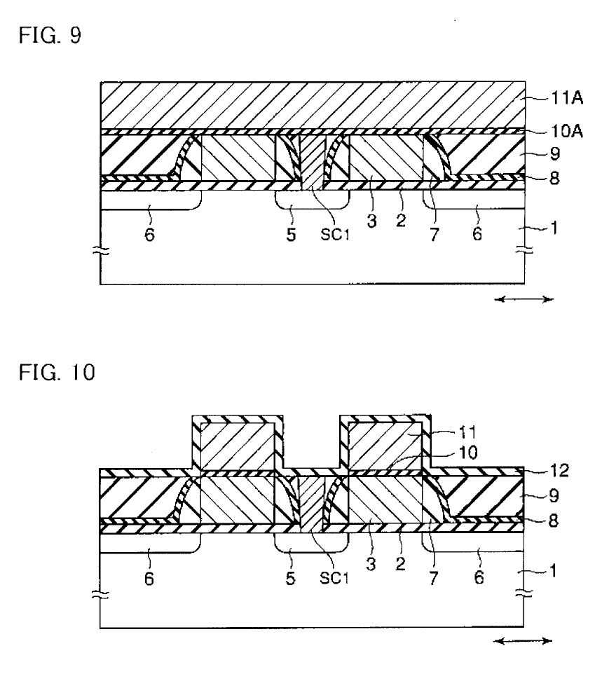

After the SiN film 8 is removed by RIE, for example, as shown in FIG. 9, ONO film 10A serving as the inter-electrode insulating film, for example, and polysilicon film 11A serving as the control gate electrode, for example, is successively deposited on the whole surface of the semiconductor substrate 1.

Thereafter, as shown in FIG. 10, the polysilicon film and the ONO film is successively etched by the RIE method so as to have a desired gate width, and the inter-electrode insulating film 10 and the control gate electrode 11 are formed.

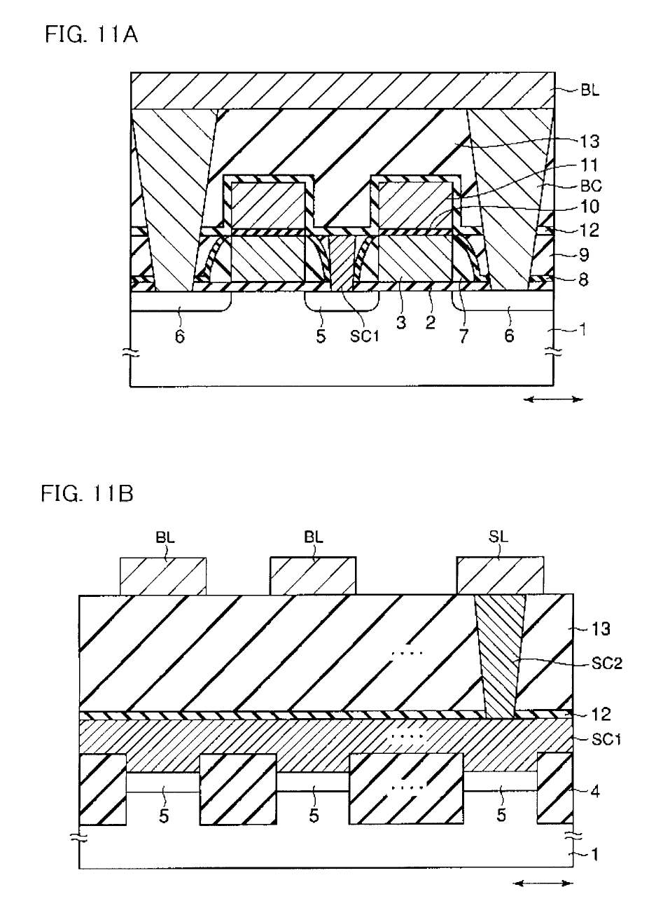

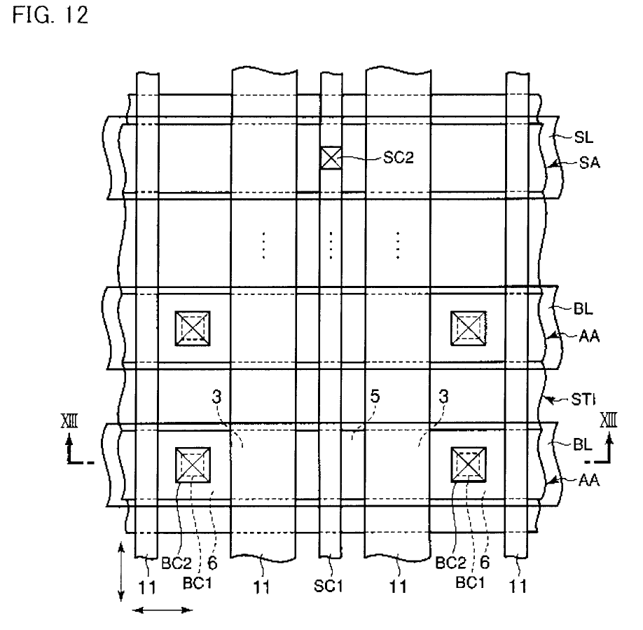

As shown in FIGS. 11A and 11B, barrier film 12 is formed so as to cover the surface of the control gate electrode 11, and then a second insulating layer 13 is deposited on the whole surface of the semiconductor substrate 1. Furthermore, the second source-line contact portion SC2 is embedded, for example, in the tapered contact hole formed in the insulating layer 13 so as to come into contact with the first source-line contact SC1.

Furthermore, the bit-line contact portion BC is embedded in an opening portion formed in the insulating layers 9, 13 so as to come into contact with the drain diffusion layer 6.

Thereafter, the bit line BL and the source line SL which are formed of metal material such as Al or Cu, for example, is formed on the upper surface of the insulating layer 13.

Through the above manufacturing process, the NOR type flash memory according to this embodiment is completed.

In the memory cell transistor manufactured by the above manufacturing process, the first source-line contact portion coming into contact with the source diffusion layer can be formed at the aspect ratio based on the height of the floating gate electrode. Accordingly, the size of the source diffusion layer can be reduced, and the miniaturization of the memory cell transistor and the reduction of the size of the memory cell array portion can be performed.

### (b) Application

In this embodiment, from the viewpoint of lithography and the embedment performance of plug material, the miniaturization effect is larger in the source-line contact portion embedded in the slit-shaped contact hole than the bit-line contact portion.

Therefore, in this embodiment, the upper end of the source-line contact portion is formed so as to be located at a lower position than the lower end of the control gate electrode, and the size in the channel length direction of the source diffusion layer can be reduced.

However, this embodiment of the present invention is applied to not only the source-line contact portion, but also the bit-line contact portion, and thus the size of the memory cell transistor can be further reduced.

In the following example, the embodiment of the present invention is applied to the source-line contact portion and the bit-line contact portion.

### (i) Structure

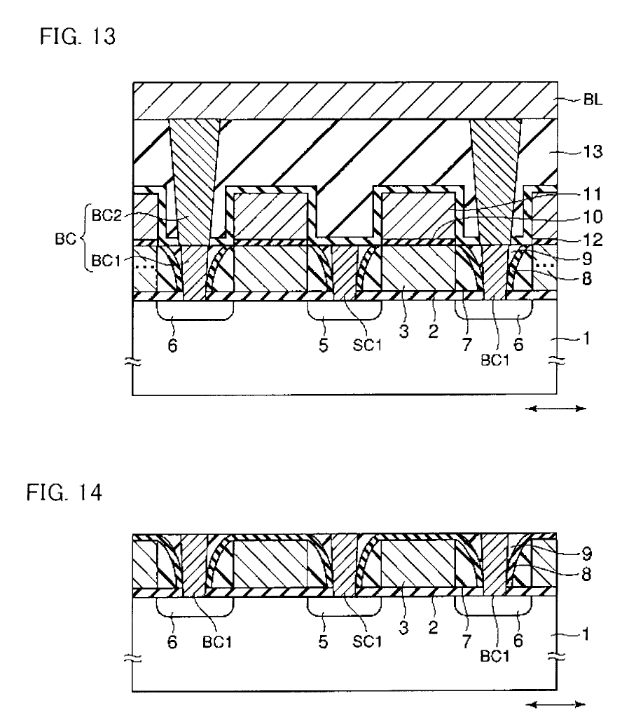

FIG. 12 is a plan view showing this application, and FIG. 13 is a cross-sectional view taken along the XIII-XIII line of FIG. 11. As shown in FIG. 13, the bit-line contact portion BC comprises a first bit-line contact portion BC1 formed at the same time as the first source-line contact portion SC1, and a second bit-line contact portion BC2 for connecting the first bit-line contact portion BC1 to the bit line BL.

In this application, the first bit-line contact portion BC1 is formed simultaneously with the first source-line contact portion SC1. That is, the contact hole in which the first bit-line contact portion BC1 will be embedded is formed at the aspect ratio based on the height (film thickness) of the floating gate electrode 3. Therefore, the aspect ratio of the contact hole can be reduced, and the size in the channel length direction of the drain diffusion layer 6 can be reduced. Accordingly, the size of the source and drain diffusion layers can be reduced, so that the memory cell transistor can be miniaturized and the size of the memory cell array portion can be reduced.

### (ii) Manufacturing Method

A method of manufacturing the structure of this application will be described.

First, in the same process as shown in FIGS. 5A and 7, the floating gate electrode 3 is formed on the gate insulating film 2 on the surface of the semiconductor substrate 1. At this time, the size of an area in which the drain diffusion layer will be formed in a subsequent step is set to be narrower than the size shown in the embodiment (basic example) described above.

Subsequently, the source and drain diffusion layers 5, 6 are formed in self-alignment on the surface of the semiconductor substrate 1 by using the floating gate electrode 3 as a mask. Thereafter, the spacer insulating layer 7, the stopper film 8 and the first insulating layer 9 are successively formed.

Then, as shown in FIG. 14, the first source-line contact portion SC1 and the first bit-line contact portion BC1 are embedded in the contact holes which are formed in the insulating layer 9 so as to come into contact with the diffusion layers 5, 6, respectively.

Subsequently, in the same process as shown in FIGS. 9 to 11A, 11B, the inter-electrode insulating film 10 and the control gate electrode 11 are successively formed, and further the barrier film 12 and the second insulating layer 13 are formed.

Then, the second source-line contact portion SC2 and the second bit-line contact portion BC2 are formed in the insulating layer 13 in the same step, for example. Thereafter, the source line SL and the bit line BL are formed on the insulating layer 13, and the NOR type flash memory of this embodiment is completed.

The memory cell transistor manufactured by the above manufacturing process can form the contact portion in contact with the diffusion layer at the aspect ratio based on the height of the floating gate electrode 3. Accordingly, the size of the source and drain diffusion layers can be reduced, the memory cell transistor can be miniaturized and the size of the memory cell array portion can be reduced.

### (d) Modification

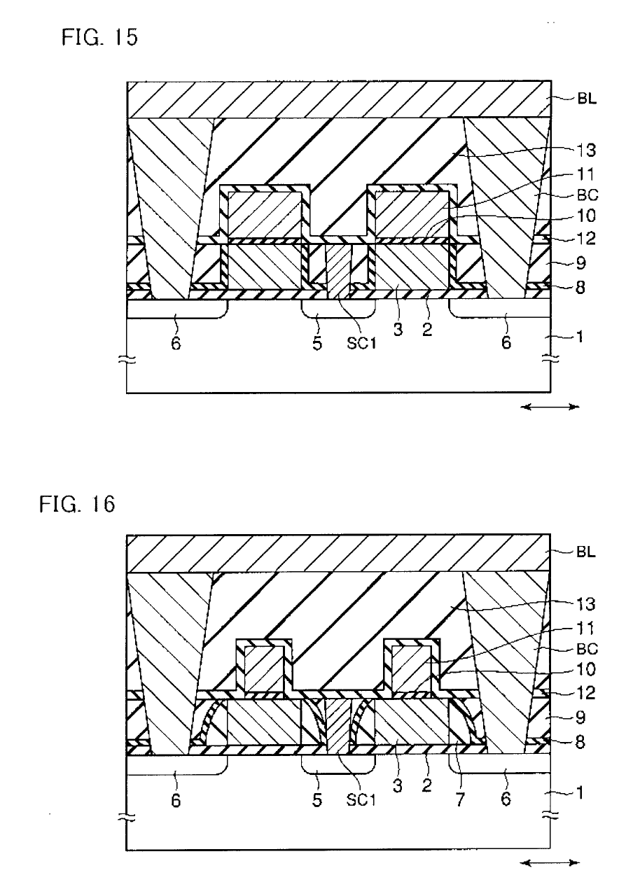

The spacer insulating layer 7 described above is not necessarily formed when the short margin between the contact portion and the gate electrode can be secured. Therefore, the memory cell of the embodiment of the present invention may be designed to have a structure shown in FIG. 15. In this case, only the first insulating layer 9 is embedded between the two floating gate electrodes 3 adjacent in the channel length direction. The first source-line contact portion SC1 is embedded in the insulating layer 9 so as to be in contact with the source diffusion layer 5. Accordingly, in the structure shown in FIG. 15, the size of the source diffusion layer 5 can be reduced, and the memory cell transistor can be miniaturized. Furthermore, the spacer insulating layer is not formed, so that the number of the manufacturing steps can be reduced and the manufacturing cost can be reduced.

This modification may be applied to the structure of the application described above.

### (2) Second Embodiment

As described above, in the NOR type flash memory according to the first embodiment, the floating gate electrode and the control gate electrode are formed in different steps in order to reduce the aspect ratio for forming the source-line contact. Therefore, the floating gate electrode and the control gate electrode may be misaligned as compared with the case where the floating gate electrode and the control gate electrode are subjected to gate processing at the same time.

In this embodiment, the structure of a memory cell transistor which can permit the misalignment (the positional displacement) between the control gate electrode and the floating gate electrode in addition to the effect of the first embodiment, and a method of manufacturing the structure concerned will be described. In the following description, the same elements as the first embodiment are represented by the reference numerals, and the detailed description thereof is omitted.

### (a) Structure

FIG. 16 is a cross-sectional view showing the structure in the channel length direction of this embodiment.

This embodiment has a feature that the width in the channel length direction of the control gate electrode 11 is smaller than the width in the channel length direction of the floating gate electrode 3. The misalignment between the control gate electrode 11 and the floating gate electrode 3 can be permitted by the above feature.

Furthermore, even when the structure of the stacked gate electrode as described above is established, the structure of the first source-line contact portion SC1 is not adversely affected. Accordingly, the size of the source diffusion layer 5 can be reduced.

Furthermore, the short-circuit between the bit line contact portion BC and the control gate electrode 11 can be also prevented. Accordingly, according to this embodiment, the memory cell transistor can be miniaturized, and the size of the memory cell array portion can be reduced. In addition, the misalignment between the stacked gate electrodes can be permitted, and the manufacturing yield of the NOR type flash memory can be enhanced.

### (b) Manufacturing Method

A manufacturing method according to this embodiment will be described.

First, the floating gate electrode 3 and the drain and source diffusion layers 5, 6 are successively formed by using the same process as shown in FIGS. 5A to 9 of the first embodiment. Subsequently, the spacer insulating layer 7, the stopper film 8 and the first insulating layer 9 are successively formed.

Thereafter, the first source-line contact portion SC1 is embedded in the insulating layer 9 so as to be in contact with the source diffusion layer 5. Furthermore, the ONO film 10A serving as the inter-electrode insulating film and the polysilicon film 11A serving as the control gate electrode are deposited.

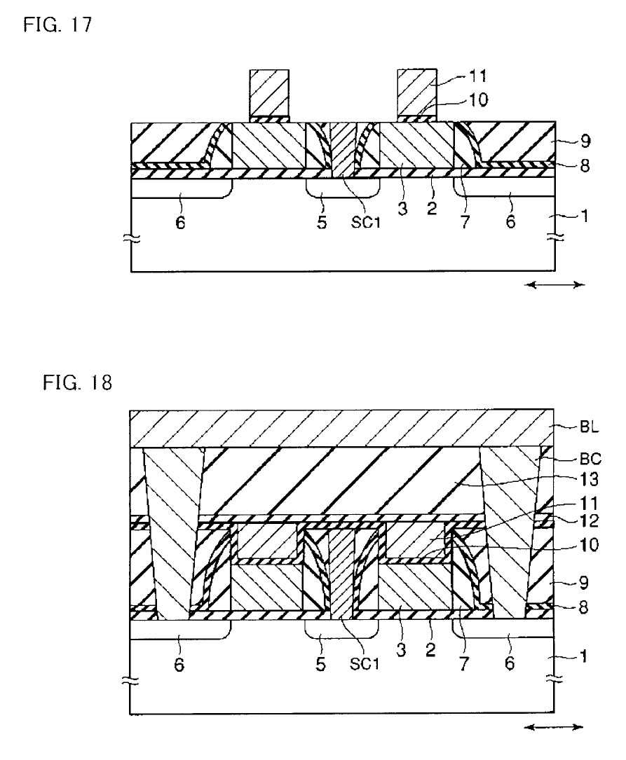

Subsequently, the polysilicon film 11A is subjected to the patterning for forming the control gate electrode. In this pattern, the size in the channel length direction of the control electrode is smaller than the size in the channel length direction of the floating gate electrode 3. When etching is carried out on the basis of the pattern concerned by the RIE method, the size in the channel length direction of the control gate electrode 11 is smaller than the size in the channel length direction of the floating gate electrode 3 as shown in FIG. 17.

Subsequently, as shown in FIG. 16, the barrier film 12 and the second insulating layer 13 are formed in the same process as shown in FIGS. 10, 11A and 11B. Furthermore, the bit-line contact portion BC is formed in the insulating layers 9, 13. Furthermore, the second source-line contact portion SC2 is embedded in the insulating layer 13 so as to be in contact with the first source-line contact portion SC1. Thereafter, the source line SL and the bit line BL are formed on the insulating layer 13, thereby completing the NOR type flash memory of this embodiment.

In the memory cell transistor manufactured by the above manufacturing process, the contact portion which comes into contact with the diffusion layer can be formed at the aspect ratio based on the height of the floating gate electrode. Accordingly, the size of the diffusion layer can be reduced, the memory cell transistor can be miniaturized and the size of the memory cell array portion can be reduced.

Furthermore, the size in the channel length direction of the control gate electrode is set to be smaller than the size in the channel length direction of the floating gate electrode, whereby the misalignment between the two stacked gate electrodes can be permitted.

The structure and the manufacturing method of the stacked gate electrodes in this embodiment are also applicable to the application and modification of the first embodiment.

### (3) Third Embodiment

As described in the second embodiment, according to the embodiments of the invention, the floating gate electrode 3 and the control gate electrode are subjected to the gate processing in different steps, and thus they are misaligned. In the second embodiment, when the control gate electrode is subjected to the gate processing, the gate processing is conducted so that the size in the channel length direction of the control gate electrode is smaller than the size in the channel length direction of the floating gate electrode, thereby permitting the misalignment between the control gate electrode and the floating gate electrode.

In this embodiment, a structure and a manufacturing method which can prevent the misalignment in a self-alignment style. The same elements as the first and second embodiments are represented by the same reference numerals, and the detailed description thereof is omitted.

### (a) Structure

FIG. 18 is a diagram showing the cross-section in the channel length direction of this embodiment.

As shown in FIG. 18, the control gate electrode 11 is embedded in self-alignment in a recess portion defined by the side surface of the spacer insulating layer 7 and the upper surface of the floating gate electrode 3. Therefore, no misalignment occurs between the floating gate electrode 3 and the control gate electrode 11.

The upper end of the first source-line contact portion SC1 is covered by the inter-electrode insulating film 10. That is, the inter-electrode insulating film is disposed on the area of the source diffusion layer 5. The upper end of the first source-line contact portion SC1 is located at a lower position than the upper end of the bit-line contact portion BC.

The control gate electrode 11 is embedded in self-alignment in the recess portion by CMP. At this time, it is desired that the upper end of the control gate electrode 11 is perfectly coincident with the upper end of the inter-electrode insulating film 10 on the source-line contact portion SC1. However, in the surface polishing based on CMP, a dishing phenomenon occurs, and thus there occurs such a case that the upper end of the control gate electrode 11 is lower than the upper end of the inter-electrode insulating film 10 on the source-line contact portion SC1. FIG. 18 shows the case where the upper end of the control gate electrode 11 is coincident with the upper end of the inter-electrode insulating film 10 on the source-line contact portion SC1.

Furthermore, in this embodiment, the recess portion in which the control gate electrode 11 is embedded is defined by the side surface of the spacer insulating layer 7 and the upper surface of the floating gate electrode 3 as shown in FIG. 18, however, this embodiment is not limited to this structure. For example, as shown in FIG. 15, when no spacer insulating layer is formed, the reception portion may be defined by the side surface of the first insulating layer 9 and the upper surface of the floating gate electrode 3.

As described above, according to this embodiment, the size of the source diffusion layer can be reduced. Therefore, the memory cell transistor can be miniaturized, and the size of the memory cell array portion can be reduced. Furthermore, the misalignment between the two stacked gate electrodes can be prevented by a self-alignment method, and the manufacturing yield of the NOR type flash memory can be enhanced.

The structure of this embodiment may be also applied to the application and modification of the first embodiment.

### (b) Manufacturing Method

The manufacturing method of this embodiment will be described.

First, the gate insulating film 2, the floating gate electrode 3 and the source and drain diffusion layers 5, 6 are successively formed by the same process as shown in FIGS. 5A and 6. At this time, the floating electrode 3 is formed to be thicker than a desired film thickness.

Subsequently, the spacer insulating layer 7, the stopper film 8 and the first insulating layer 9 are successively formed by the same step as shown in FIGS. 7 and 8. Then, the first source-line contact portion SC1 is embedded in a contact hole formed in the first insulating layer 9 so as to be in contact with the source diffusion layer 5.

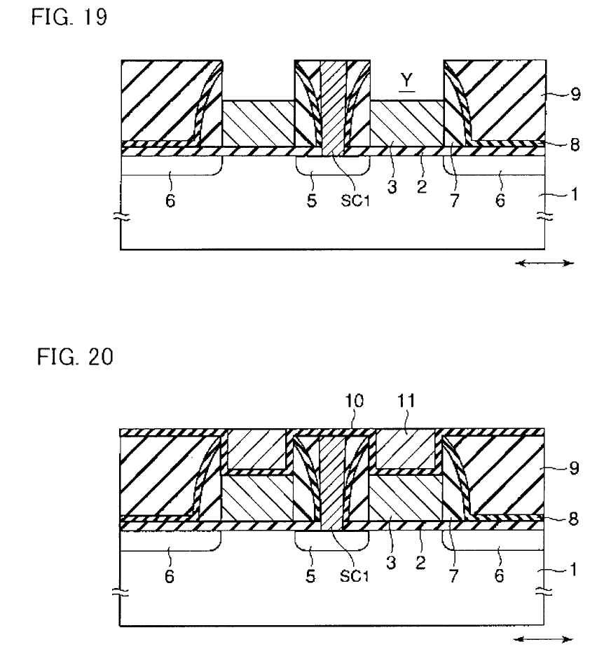

Thereafter, the floating gate electrode 3 is selectively etched by RIE as shown in FIG. 19, for example, whereby a recess portion Y defined by the upper surface of the floating gate electrode 3 and the side surface of the spacer insulating layer 7 is formed on the channel region. In this etching step, the floating gate electrode 3 is formed to have a desired film thickness, for example.

Subsequently, as shown in FIG. 20, the inter-electrode insulating film 10 is formed on the floating gate electrode 3 and on the first source-line contact portion SC1. Then, polysilicon is embedded in the recess portion so as to be coincident with the upper end of the inter-electrode insulating film by CVD or CMP, for example. Accordingly, the control gate electrode 11 is formed in self-alignment on the floating gate electrode 3 through the inter-electrode insulating film 10.

Thereafter, the barrier film 12 and the second insulating layer 13 are successively formed by the same process as shown in FIGS. 10, 11A and 11B. Furthermore, the second source-line contact portion SC2, the bit-line contact portion BC, the source line SL and the bit line BL are formed, thereby completing the NOR type flash memory of this embodiment shown in FIG. 18.

In this embodiment, it is not necessarily to form the barrier film 12.

In the memory cell transistor manufactured by the above manufacturing process, the contact portion which is in contact with the diffusion layer can be formed at the aspect ratio based on the height of the floating gate electrode. Accordingly, the size of the source diffusion layer can be reduced, the memory cell transistor can be miniaturized and the size of the memory cell array portion can be reduced.

Furthermore, according to the foregoing manufacturing method, the misalignment between the control gate electrode and the floating gate electrode can be prevented by the self-alignment method, and thus the manufacturing yield of the NOR type flash memory can be enhanced.

The manufacturing method of this embodiment is also applicable to the application and modification of the first embodiment. According to the present invention, the memory cell transistor can be micro-structured (miniaturized), and the size of the memory cell array portion can be reduced.

The present invention is not limited to the above-described embodiments, and various modifications may be made to the respective constituent elements without departing from the subject matter of the present invention. Various embodiments may be constructed by properly combining plural constituent elements disclosed in the above-described embodiments. For example, some constituent elements may be deleted from all the constituent elements disclosed in the above-described embodiments, or constituent elements of different embodiments may be properly combined.

Additional advantages and modifications will readily occur to those skilled in the art. Therefore, the invention in its broader aspects is not limited to the specific details and representative embodiments shown and described herein.

Accordingly, various modifications may be made without departing from the spirit or scope of the general inventive concept as defined by the appended claims and their equivalents.

What is claimed is:

1. A method of manufacturing a nonvolatile semiconductor memory comprising:
forming a gate insulating film formed on a surface of a semiconductor substrate;
forming a source region and a drain region in the semiconductor substrate;
forming a floating gate electrode on the gate insulating film;
forming a inter-gate insulating film on the floating gate electrode;
forming a control gate electrode on the inter-gate insulating film;
forming a source contact region wherein the source contact region is electrically contact to said source region, and top part of said source contact region is lower than bottom part of said control gate electrode.

2. The method of manufacturing a nonvolatile semiconductor memory according to claim 1, wherein the said inter-gate insulating film covers the top of said source contact region.
